(19) United States
(12) Patent Application Publication
(10) Pub. No.: US 2025/0393213 A1
(43) Pub. Date: Dec. 25, 2025

(54) MEMORY ARCHITECTURES WITH SPLIT PILLARS

(71) Applicant: Micron Technology, Inc., Boise, ID (US)

(72) Inventors: Lorenzo Fratin, Buccinasco (IT); Paolo Tessariol, Arcore (IT); Paolo Fantini, Vimercate (IT); Enrico Varesi, Milano (IT)

(21) Appl. No.: 19/235,262

(22) Filed: Jun. 11, 2025

Related U.S. Application Data
(60) Provisional application No. 63/661,819, filed on Jun. 19, 2024.

(51) Int. Cl. H10B 43/27; G11C 5/06; G11C 16/04; H10B 43/10; H10B 43/35; H10D 30/01; H10D 30/69; H10D 62/17

(52) U.S. Cl. CPC H10B 43/27; G11C 5/063; G11C 16/0483; H10B 43/10; H10B 43/35; H10D 30/0413; H10D 30/693; H10D 62/292

(57) ABSTRACT

Methods, systems, and devices for memory architectures with split pillars are described. A memory device may include multiple piers each including a first not AND (NAND) channel coupled with a first bit line at a first end and a second NAND channel coupled with a second bit line at a second end. In such examples, an edge of the first NAND channel may be offset from an edge of the first bit line. Similarly, an edge of the second NAND channel may be offset from an edge of the second bit line. The memory device may include a dielectric material separating the first NAND channel and the first bit line from the second NAND channel and the second bit line of each pier. Additionally, the memory device may include multiple word lines, where each word line may be coupled with the first and the second NAND channels of each pier.

### CROSS REFERENCE

The present Application for Patent claims priority to U.S. Patent Application No. 63/661,819 by Fratin et al., entitled “MEMORY ARCHITECTURES WITH SPLIT PILLARS,” filed Jun. 19, 2024, which is assigned to the assignee hereof, and which is expressly incorporated by reference in its entirety herein.

### TECHNICAL FIELD

The following relates to one or more systems for memory, including memory architectures with split pillars.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a system that supports memory architectures with split pillars in accordance with examples as disclosed herein.

FIG. 2 shows an example of a memory architecture that supports memory architectures with split pillars in accordance with examples as disclosed herein.

FIG. 3 shows an example of a memory device that supports memory architectures with split pillars in accordance with examples as disclosed herein.

FIG. 4 shows an example of a processing step that supports memory architectures with split pillars in accordance with examples as disclosed herein.

FIG. 5 shows an example of a processing step that supports memory architectures with split pillars in accordance with examples as disclosed herein.

FIG. 6 shows an example of a processing step that supports memory architectures with split pillars in accordance with examples as disclosed herein.

FIG. 7 shows an example of a processing step that supports memory architectures with split pillars in accordance with examples as disclosed herein.

FIG. 8 shows an example of a processing step that supports memory architectures with split pillars in accordance with examples as disclosed herein.

FIG. 9 shows an example of a processing step that supports memory architectures with split pillars in accordance with examples as disclosed herein.

FIG. 10 shows a flowchart illustrating a method or methods that support memory architectures with split pillars in accordance with examples as disclosed herein.

### DETAILED DESCRIPTION

Some memory devices, not AND (NAND) memory devices, may include three dimensional (3D) architectures. For example, a memory device may include multiple pillars, where each pillar of the multiple pillars may include multiple memory cells (formed along the z direction). In some cases, however, such devices may be limited in scale. For example, a density of a 3D memory device architecture, among other features, may be limited during manufacturing, thereby reducing a quantity of memory cells formed (e.g., integrated) in each device. Thus, techniques may be desired to increase a density of 3D memory devices, without incurring additional costs, without incurring additional manufacturing times, and without reducing the sustainability (e.g., lifetime or quality) of the memory cells.

According to the techniques described herein, to increase the scalability of memory devices, a memory device may be formed that includes multiple piers (e.g., pillars), where each pier of the multiple piers may include a first NAND channel and a first bit line at a first end of the pier and a second NAND channel and a second bit line at a second end of the pier. In such examples, each NAND channel of a single pier may include multiple memory cells, such that a single pier may have a first set of multiple memory cells (in the z direction) at the first end (e.g., the first NAND channel) and a second set of multiple memory cells (along the z direction) at the second end (e.g., the second NAND channel).

Each pier of the multiple piers may include a core dielectric material, where the core dielectric material of each pier may be coupled with a dielectric material (channel). The core dielectric material and the dielectric channel may provide support for the piers and also separate the first NAND channel and the first bit line from the second NAND channel and second bit line of each pier of the multiple piers, thereby avoiding shorts between the two. Additionally, the memory device may include multiple word lines, where each word line of the multiple word line may be coupled with a respective memory cell of each NAND channel of each pier of the multiple piers. In this way, by forming piers that each include a first and second NAND channel, the memory device may include (e.g., integrate) an increased quantity of memory cells per pier (e.g., double the memory cells) relative to other memory devices (e.g., a single pillar with a single set of multiple memory cells).

In some examples, to maintain a quality of the memory cells along each NAND channel of a single pier, the NAND channels and bit lines may be formed with a hemicylindrical form, which may increase the strength of the electrical field at the center of each memory cell along the NAND channels, thereby maintaining, or improving, the sustainability of the memory cells. Further, to prevent various read disturbances that may occur while accessing a memory cell along a respective NAND channel of the pier, the edges of each NAND channel may be offset from the edges of each bit line, such that the charge stored by each memory cell of the NAND channels may concentrate in a center (middle portion of the curvature) of each memory cell, thereby reducing variations in a threshold voltage at each memory cell.

In addition to applicability in memory systems as described herein, techniques for memory architectures with split pillars may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by splitting the NAND channel of each pier (e.g., pillar) into a first and second NAND channel, thereby increasing the quantity of memory cells within a memory device, which may reduce electronic waste, extend the life of electronic devices and thereby reducing electronic waste, among other benefits.

Features of the disclosure are illustrated and described in the context of systems, devices, and circuits. Features of the disclosure are further illustrated and described in the context of memory devices, processing steps, and flowcharts.

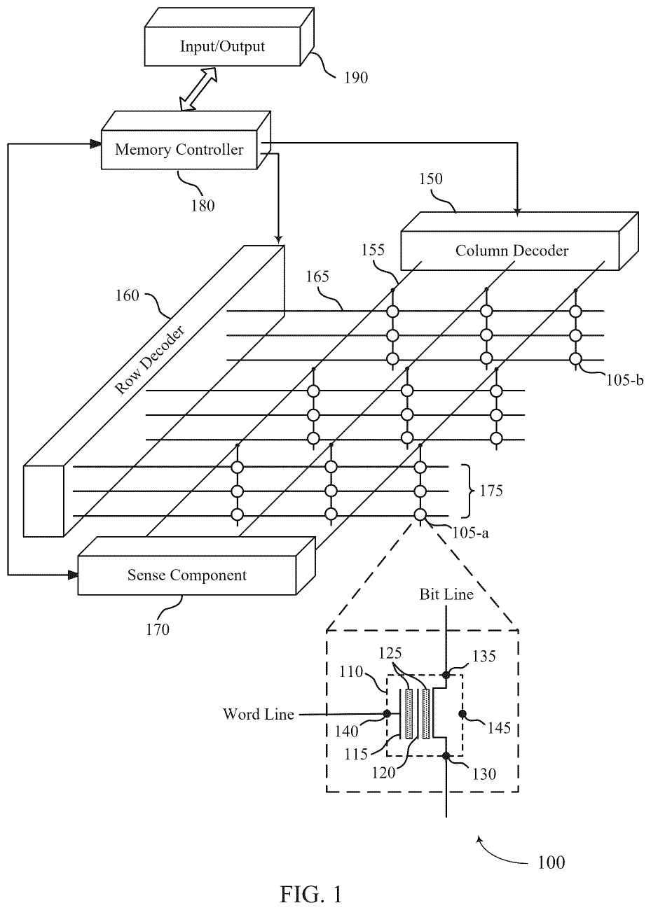

FIG. 1 shows an example of a memory device 100 that supports memory architectures with split pillars in accordance with examples as disclosed herein. FIG. 1 is an illustrative representation of various components and features of the memory device 100. As such, the components and features of the memory device 100 are shown to illustrate functional interrelationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features.

The memory device 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

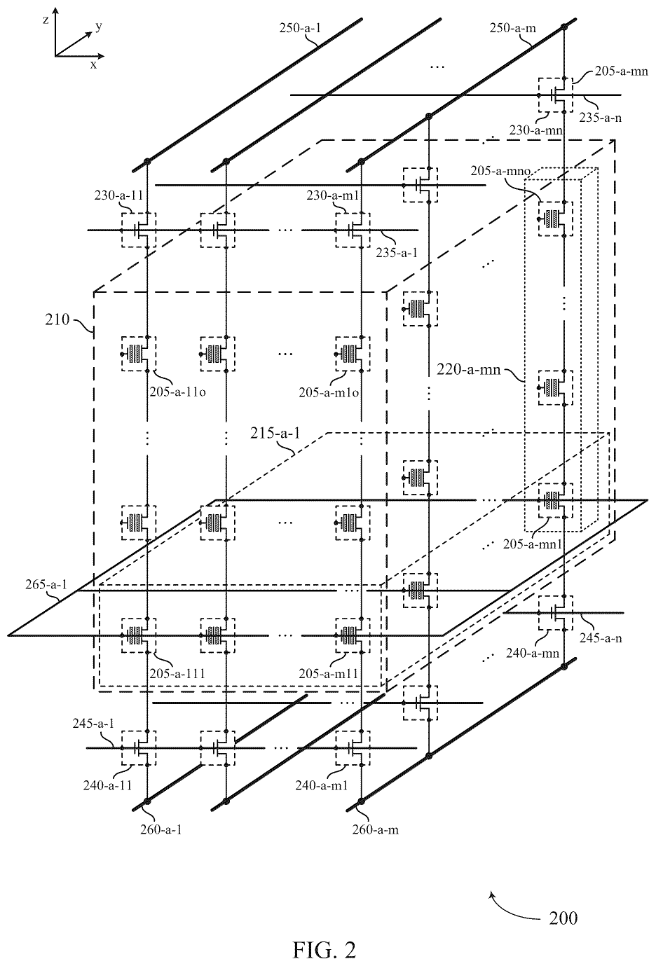

In some cases, a memory device 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory device 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory device 100.

According to the techniques described herein, to increase the scalability of memory devices (e.g., 3D NAND memory devices), a memory device may be formed that includes multiple piers, where each pier of the multiple piers may include a first NAND channel and a first bit line 155 at a first end of the pier and a second NAND channel and a second bit line 155 at a second end of the pier. In such examples, each NAND channel of a single pier may include multiple memory cells 105, such that a single pier may have a first set of multiple memory cells 105 (in the z direction) at the first end (e.g., the first NAND channel) and a second set of multiple memory cells 105 (along the z direction) at the second end (e.g., the second NAND channel).

Each pier of the multiple piers may include a core dielectric material, where the core dielectric material of each pier may be coupled with a dielectric material (channel). The core dielectric material and the dielectric channel may provide support for the piers and also separate the first NAND channel and the first bit line 155 from the second NAND channel and second bit line 155 of each pier of the multiple piers, thereby avoiding shorts between the two. Additionally, the memory device may include multiple word lines 165, where each word line 165 of the multiple word lines 165 may be coupled with a respective memory cell 105 of each NAND channel of each pier of the multiple piers. In this way, by forming piers that each include a first and second NAND channel, the memory device may include (e.g., integrate) an increased quantity of memory cells 105 per pier (e.g., double the memory cells 105) relative to other memory devices (e.g., a single pillar with a single set of multiple memory cells 105).

In some examples, to maintain a quality of the memory cells 105 along each NAND channel of a single pier, the NAND channels and bit lines 155 may be formed with a hemicylindrical form, which may increase the strength of the electrical field at the center of each memory cell along the NAND channels, thereby maintaining, or improving, the sustainability of the memory cells 105. Further, to prevent various read disturbances that may occur while accessing a memory cell along a respective NAND channel of the pier, the edges of each NAND channel may be offset from the edges of each bit line 155, such that the charge stored by each memory cell of the NAND channels may concentrate in a center (middle portion of the curvature) of each memory cell, thereby reducing variations in a threshold voltage at each memory cell.

FIG. 2 shows an example of a memory architecture 200 that supports memory architectures with split pillars in accordance with examples as disclosed herein. The memory architecture 200 may be an example of a portion of a memory device, such as a memory device 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory device 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

According to the techniques described herein, to increase the scalability of memory devices (e.g., 3D NAND memory devices), a memory device may be formed that includes multiple piers, where each pier of the multiple piers may include a first NAND channel and a first bit line 250 at a first end of the pier and a second NAND channel and a second bit line 250 at a second end of the pier. In such examples, each NAND channel of a single pier may include multiple memory cells 205, such that a single pier may have a first set of multiple memory cells 205 (in the z direction) at the first end (e.g., the first NAND channel) and a second set of multiple memory cells 205 (along the z direction) at the second end (e.g., the second NAND channel).

Each pier of the multiple piers may include a core dielectric material, where the core dielectric material of each pier may be coupled with a dielectric material (channel). The core dielectric material and the dielectric channel may provide support for the piers and also separate the first NAND channel and the first bit line 250 from the second NAND channel and second bit line 250 of each pier of the multiple piers, thereby avoiding shorts between the two. Additionally, the memory device may include multiple word lines 265, where each word line 265 of the multiple word lines 265 may be coupled with a respective memory cell 205 of each NAND channel of each pier of the multiple piers. In this way, by forming piers that each include a first and second NAND channel, the memory device may include (e.g., integrate) an increased quantity of memory cells 205 per pier (e.g., double the memory cells 205) relative to other memory devices (e.g., a single pillar with a single set of multiple memory cells 205).

In some examples, to maintain a quality of the memory cells 205 along each NAND channel of a single pier, the NAND channels and bit lines 250 may be formed with a hemicylindrical form, which may increase the strength of the electrical field at the center of each memory cell along the NAND channels, thereby maintaining, or improving, the sustainability of the memory cells 205. Further, to prevent various read disturbances that may occur while accessing a memory cell along a respective NAND channel of the pier, the edges of each NAND channel may be offset from the edges of each bit line 250, such that the charge stored by each memory cell of the NAND channels may concentrate in a center (middle portion of the curvature) of each memory cell, thereby reducing variations in a threshold voltage at each memory cell.

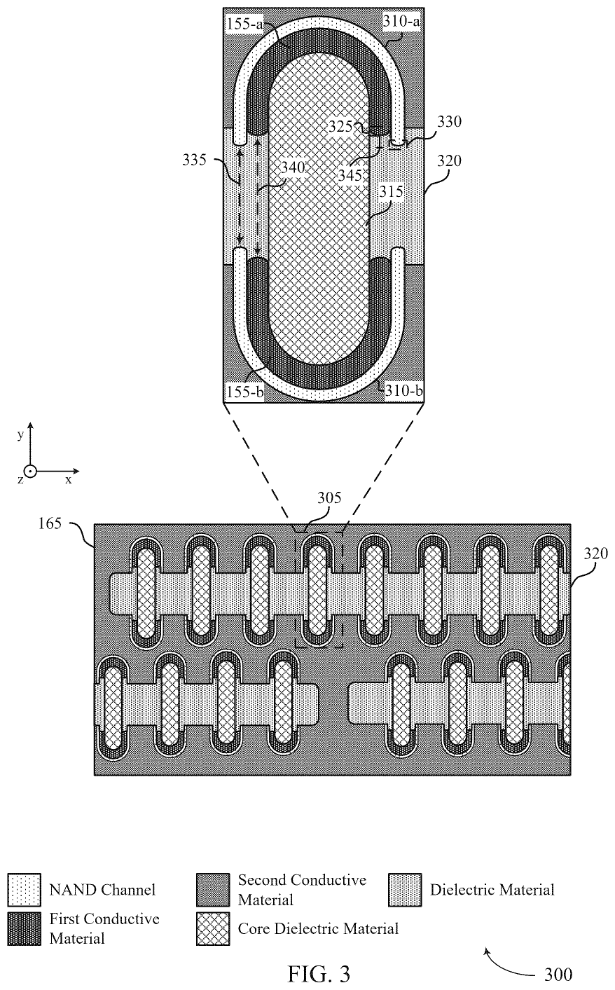

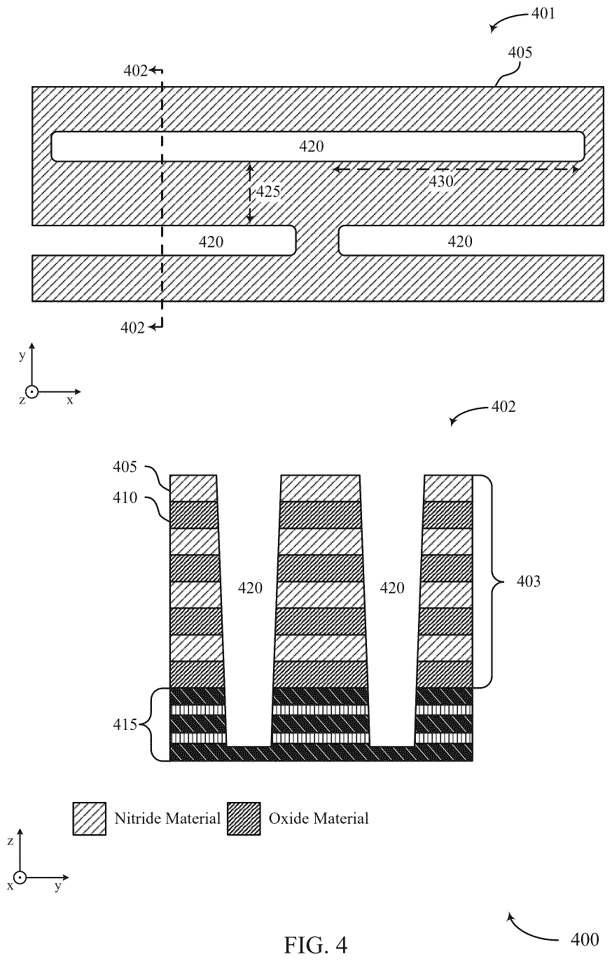

FIG. 3 shows an example of a memory device 300 that supports memory architectures with split pillars in accordance with examples as disclosed herein. Aspects of the memory device 300 may be implemented by the memory device 100 and the memory architecture 200 as described herein. For example, the memory device 300 may be an example of the memory device 100 as described herein with reference to FIG. 1. The memory device 300 may be formed according to techniques further described herein with reference to FIGS. 4 through 9 and may be formed to include an increased quantity of memory cells (relative to memory cells including a single pillar with a single set of memory cells), while also maintaining the sustainability and quality of the memory cells.

For example, the memory device 300 may include multiple piers 305 (e.g., pillars), where each pier 305 of the multiple piers 305 may include a NAND channel 310-a (e.g., a first NAND channel) and a bit line 155-a (e.g., a first bit line) at a first end (in the positive y direction) and include a NAND channel 310-b (e.g., a second NAND channel) and a bit line 155-b (e.g., a second bit line) at a second end (in the negative y direction). Each pier may extend along the z direction, such that each NAND channel 310 may include multiple respective memory cells 105 along the z direction. For example, the NAND channel 310-a of each pier 305 may have a first set of memory cells 105 that extend along the z direction, while the NAND channel 310-b of each pier 305 may have a second set of memory cells 105 that extend along the z direction. As such, each pier 305 of the multiple piers 305 may include a first set of memory cells 105 at a first end of the pier 305 and include a second set of memory cells 105 at a second end of the pier 305.

Each pier 305 may also include a core dielectric material 315, where the core dielectric material 315 of each pier 305 may be coupled with (e.g., in contact with or connected to) a dielectric material 320 (e.g., dielectric channel). The core dielectric material 315 and the dielectric material 320 may provide support for the NAND channels 310 and bit lines 155 and also separate the NAND channel 310-a and the bit line 155-a from the NAND channel 310-b and the bit line 155-b. That is, the dielectric material 320 may separate the NAND channels 310 and the bit lines 155 from one another at each pier 305.

The memory device 300 may also include multiple word lines 165, where each word line 165 of the multiple word lines 165 may be located at a respective level of the memory device 300 along the z direction, such that each word line 165 may couple with a respective memory cell 105 of the NAND channels 310 of each pier 305. Accordingly, to access a memory cell 105 at a first level of the NAND channel 310-a of the pier 305, a bit line driver may apply a voltage to the bit line 155-a and a word line driver may apply a voltage to a word line 165 that corresponds to the first level of the NAND channels 310.

As described herein, the bit lines 155 may be formed using a first conductive material, while the word lines 165 may be formed using a second conductive material. In such examples, the first conductive material and the second conductive material may be the same, while in other examples, the first conductive material may be different from the second conductive material. Some examples of conductive materials may include a metal material, polycrystalline silicon, polysilicon, or a combination thereof. In some examples, the dielectric material 320 and the core dielectric material 315 may be a same dielectric, while in other examples, the dielectric material 320 and the core dielectric material 315 may be different.

As such, by forming each pier 305 to have a NAND channel 310-a and a NAND channel 310-b, the memory device 300 may have a greater quantity of memory cells 105 relative to other memory devices 300 having a single pillar with a single set of memory cells 105 along the pillar. That is, by forming the piers 305 to have a split pillar structure, the memory device 300 may have an increased array density.

In some examples, to maintain a quality of the memory cells 105 105 along each NAND channel 310 of each pier 305, the NAND channels 310 and bit lines 155 may have one of a hemicylindrical form, a semielliptical form, a rounded rectangular form, or a combination thereof, which may increase the strength of the electrical field at the center of each memory cell 105 along the NAND channels 310, thereby maintaining, or improving, the sustainability of the memory cells 105. For example, the curvature form of the NAND channels 310 may reduce memory cell 105 to memory cell 105 interference due to the electric field lines being contained within the memory cell 105, thereby reducing the likelihood of such electric fields affecting neighboring memory cells 105. Additionally, the curvature form of the NAND channels 310 may improve the endurance of the memory cells 105. That is, because the electric field of each cell may be more evenly distributed across the memory cell 105, the stress on any one point of the memory cell 105 may be reduced, thus increasing the lifespan of the memory cell 105.

Further, to prevent various read disturbances that may occur while accessing a memory cell 105 along a respective NAND channel 310 of the pier 305, the edges 330 of each NAND channel 310 may be offset from the edges 325 of each bit line 155 in the y direction (e.g., first direction) by a distance 345 (e.g., first and second distances), such that the charge stored by each memory cell 105 of the NAND channels 310 may concentrate in a center (middle portion of the curvature) of each memory cell 105. For example, the electric field within the memory cell 105 may vary, with variations being relatively larger near the edges of the NAND channels 310 than those observed in the center of the NAND channels 310. Due to this, the threshold voltage of each memory cell 105 along the NAND channel 310 may vary based on the location of the charge stored within the memory cell 105.

Thus, to reduce such variations, the edges 330 of the NAND channels 310 may be offset from the edges 325 of the bit lines 155 in the y direction by the distance 345 to concentrate the charge stored in memory cells 105 at a center portion of the NAND channels 310. In such examples, as illustrated with respect to FIG. 3, the edges 330 of the NAND channels 310 may extend beyond (e.g., extend further than) the edges 325 of the bit lines 155 in the y direction by the distance 345. In some examples, the respective distances 345 within each pier 305 (e.g., the four distances 345 between respective edges 330 and 325) may be equivalent, such that each edge 330 of the NAND channels 310 extend beyond the edges 325 of each bit line 155-a by a same distance. Alternatively, the respective distances 345 within each pier 305 may be different.

Additionally, due such offsets, a distance 335 (e.g., third distance) between the edges 330 of the NAND channel 310-a and the NAND channel 310-b may be less than a distance 340 (e.g., fourth distance) between the edges 325 of the bit lines 155-a and the bit lines 155-b. In such examples, and as illustrated in FIG. 3, the NAND channels 310 may embrace (e.g., cover) completely the bit lines 155.

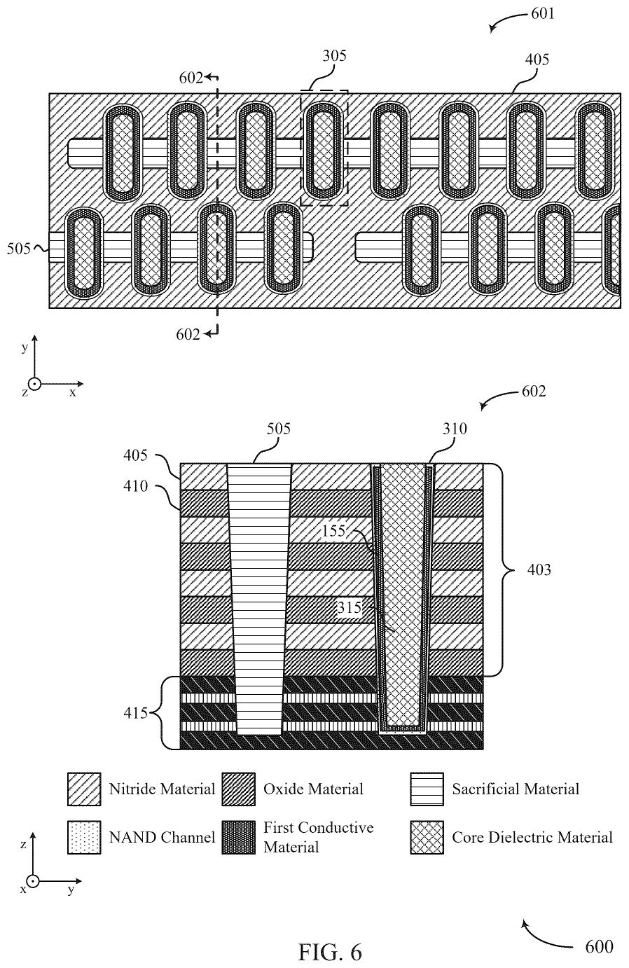

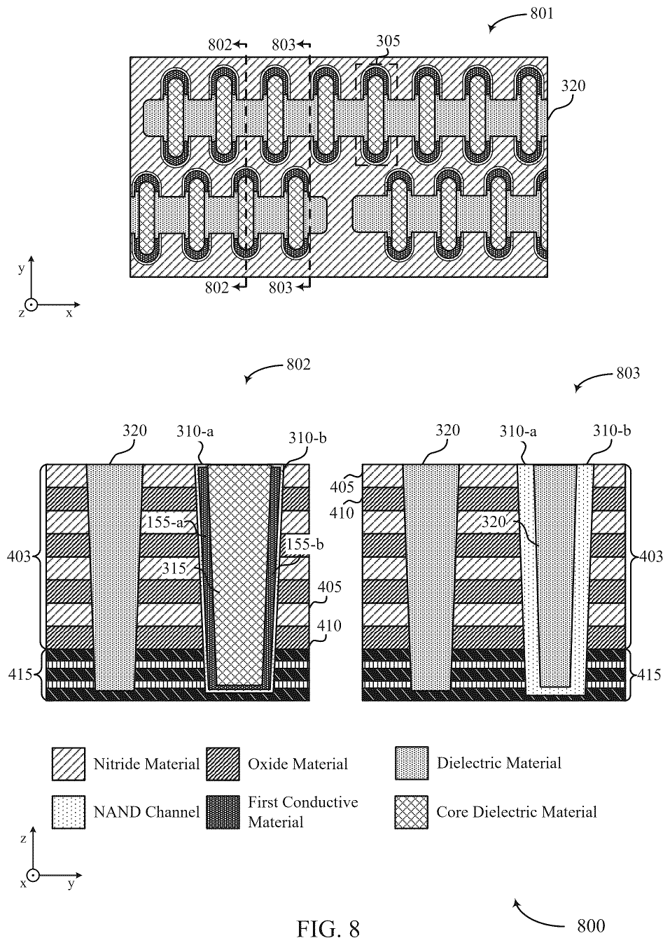

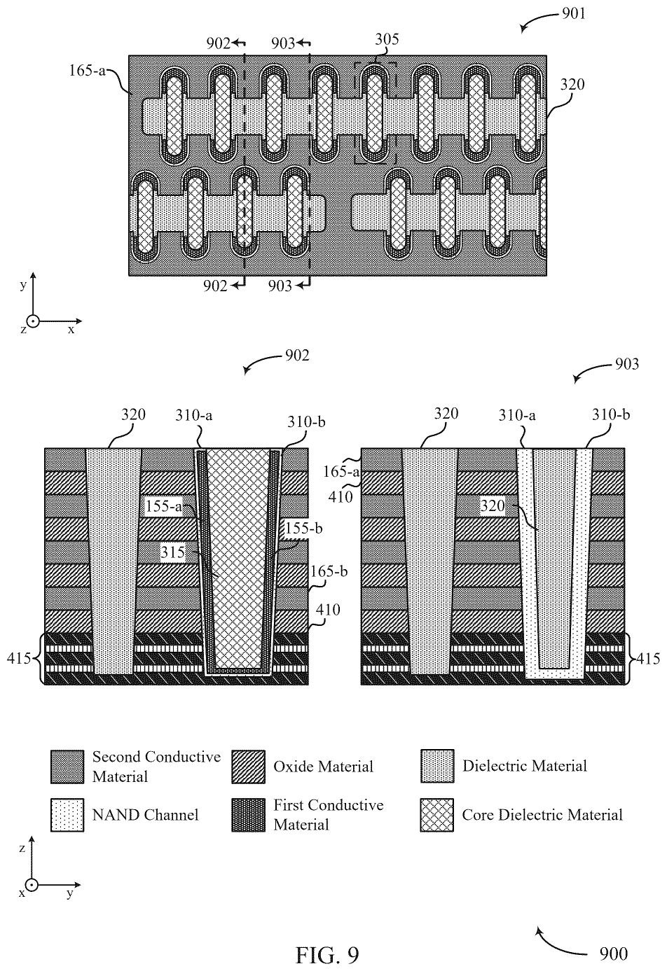

Techniques to manufacture the piers 305 may be further described herein with reference to FIG. 6. Techniques to split the piers 305 to have two NAND channels 310 and two bit lines 155 may be further described herein with reference to FIG. 8. Techniques to form the word lines 165 at each level of the piers 305 may be further described herein with reference to FIG. 9.

FIG. 4 shows an example of a processing step 400 that supports memory architectures with split pillars in accordance with examples as disclosed herein. Aspects of the processing step 400 may be implemented to manufacture the memory device 300 as described herein with reference to FIG. 3.

For example, during the manufacture of the memory device 300, a stack of materials 403 may be deposited over a substrate 415, where the stack of materials 403 may include alternating nitride materials 405 and oxide materials 410. In such examples, the substrate 415 may be a doped poly material.

Based on forming the stack of materials 403 over the substrate 415, multiple trenches 420 may be formed through the stack of materials 403. For example, an etching procedure may be performed, such as a wet etching, dry etching, or a combination of both, to form the trenches 420. As illustrated in the view 401 (e.g., top down view), the trenches 420 may be formed along the x direction of the stack of materials 403. Additionally, as illustrated in the view 402 (e.g., a cross sectional view), each trench 420 may extend, in the z direction, into the substrate 415, where each trench may have a tapered profile (e.g., a width at the top of the trenches 420 is greater than a width at the bottom of the trenches 420).

In such examples, to ensure the mechanical stability of the vertical walls of the stack of materials 403 after the formation of the trenches 420, a length 430 of the trenches 420 (e.g., in the x direction) may be selected according to a ratio between the length 430 and a distance 425 (e.g., a distance in the y direction between each trench 420), such that the ratio of the length 430 (x) to the distance 425 (y) may be less than N, where N is equal to 10-20 nanometers and may be based on the materials used in the stack of materials 403.

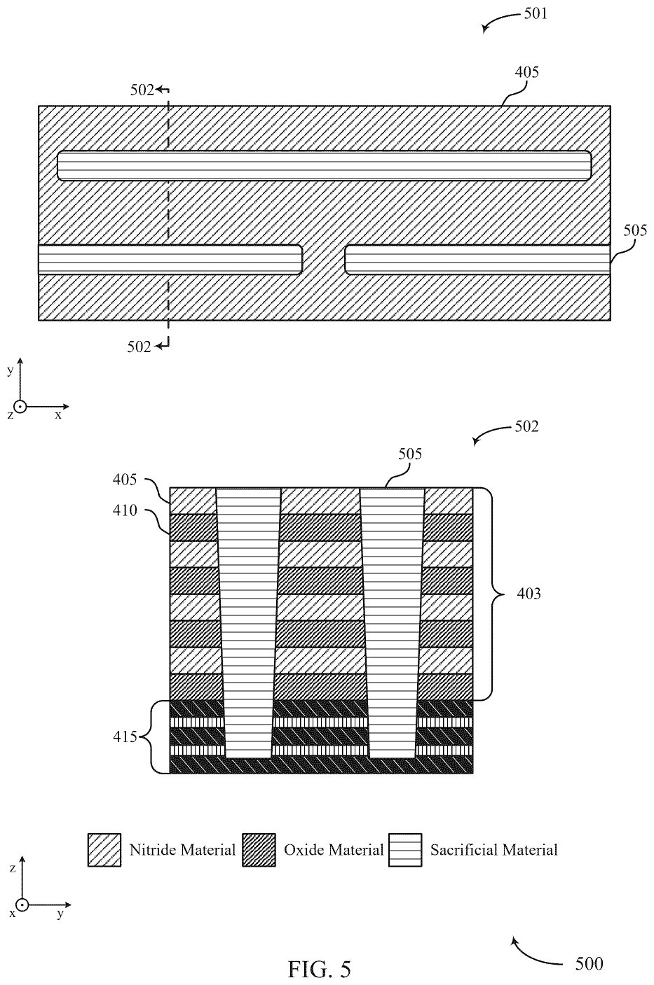

FIG. 5 shows an example of a processing step 500 that supports memory architectures with split pillars in accordance with examples as disclosed herein. Aspects of the processing step 500 may be implemented to manufacture the memory device 300 as described herein with reference to FIG. 3. The processing step 500 may be performed in response to (e.g., after) the processing step 400. For example, based on forming the trenches 420 at the processing step 400, a sacrificial material 505 may be deposited into each trench 420. With respect to the view 501 (e.g., top down view), the sacrificial material 505 may be deposited into each trench 420 such that the sacrificial material 505 spans the entire trench in the x and y directions. Additionally, with respect to the view 502 (e.g., cross sectional view), the sacrificial material 505 may be deposited into each trench such that the sacrificial material 505 extends into the substrate 415. In such examples, the sacrificial material may be Silicon Carbon Nitride (SiCN), doped or undoped poly Silicon, Carbon, hafnium oxide (HfOx), aluminum oxide (AlOx), Carbon Nitride (CN) or a multi-layer combination of such materials.

FIG. 6 shows an example of a processing step 600 that supports memory architectures with split pillars in accordance with examples as disclosed herein. Aspects of the processing step 600 may be implemented to manufacture the memory device 300 as described herein with reference to FIG. 3. The processing step 600 may be performed in response to (e.g., after) the processing step 500 and be used to manufacture each pier 305.

With respect to the view 601 (e.g., top view), multiple piers 305 may be formed into the stack of materials 403 based on depositing the sacrificial material 505, where, as described herein with reference to FIG. 3, each pier 305 may be formed have a cylindrical form, an elliptical form, a rounded rectangular form, or a combination thereof. That is, based on depositing the sacrificial material 505, a pier etch may be performed, memory cell formation within the piers 305 and pier filling may be performed, where the pier filling may be performed subsequent to the memory cell formation within the piers 305 using a selective oxide to nitride recess to accommodate the memory cells 105.

For example, to form the piers 305, multiple cavities may be formed into the sacrificial material 505 and stack of materials 403 along the x direction (e.g., pier etch). In response to etching the multiple cavities, the NAND channel 310 of each pier may be formed in each of the multiple cavities (e.g., cell formation). In response to forming the NAND channel 310, a second cavity may be etched into each NAND channel 310, where, based on etching the second cavities, the first conductive material (e.g., material for the bit line 155) may be formed into each second cavity (e.g., bit line formation). Based on forming the first conductive material, a third cavity may be formed into each first conductive material, where, based on etching the third cavities, the core dielectric material 315 may be deposited into each third cavity, thereby forming the piers 305 (e.g., pier filling).

In some examples, in response to etching the multiple cavities and to form the piers 305, a sequential deposition may be performed into each of the multiple cavities. For example, the NAND channel 310, the first conductive material (e.g., material for the bit line 155), and the core dielectric material 315 may be deposited sequentially into the multiple cavities.

Accordingly, in response to forming the piers 305 and with respect to the view 602 (e.g., cross sectional view), each pier 305 may include a core dielectric material 315 at the center of each pier 305, a bit line 155 (formed of the conductive material) touching the core dielectric material 315, and a NAND channel 310 coupled with the bit line 155 and touching a sidewall of the stack of materials 403.

In some examples, with respect to the view 602, the core dielectric material 315 may extend through the NAND channel 310 and the bit line 155 to the substrate 415, such that the core dielectric material 315 separates the NAND channel 310 and the bit line 155 at a bottom (in the z direction) of each pier 305 (not shown). Alternatively, as illustrated in the view 602, the NAND channel 310 and the bit line 155 may connected at the bottom of each pier 305, where the core dielectric material 315 may separate the walls of the NAND channel 310 and the bit line 155 of each pier 305.

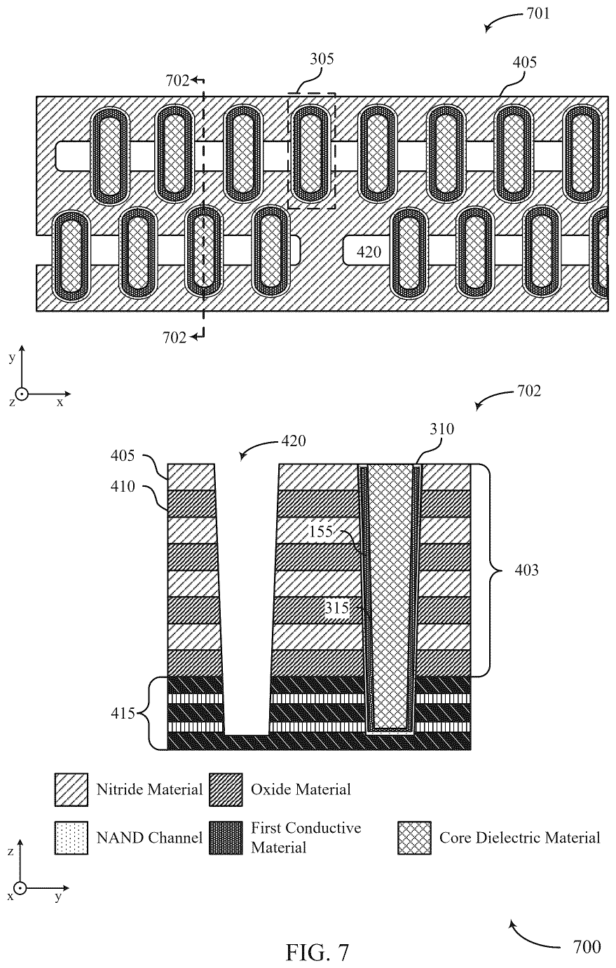

FIG. 7 shows an example of a processing step 700 that supports memory architectures with split pillars in accordance with examples as disclosed herein. Aspects of the processing step 700 may be implemented to manufacture the memory device 300 as described herein with reference to FIG. 3. The processing step 700 may be performed in response to (e.g., after) the processing step 600. In some examples, in response to forming the piers 305 in the processing step 600, the sacrificial material 505 may be exhumed to reform the trenches 420. That is, an etching procedure may be performed to remove the sacrificial material 505 to reform a portion of the trenches 420. For example, with respect to the view 701 (e.g., a top view), the sacrificial material may be exhumed to reform various portions of the trenches 420, where such portions may be between each pier 305. Accordingly, with respect to the view 702 (e.g., a cross sectional view), the portions of the trenches 420 may extend through the stack of materials 403 and into the substrate 415.

FIG. 8 shows an example of a processing step 800 that supports memory architectures with split pillars in accordance with examples as disclosed herein. Aspects of the processing step 800 may be implemented to manufacture the memory device 300 as described herein with reference to FIG. 3. The processing step 800 may be performed in response to (e.g., after) the processing step 700 and be performed to split the NAND channel 310 and bit line 155 of each pier 305 into the NAND channel 310-a and the bit line 155-a and the NAND channel 310-b and the bit line 155-b.

In some examples, in response to exhuming the sacrificial material 505 at the processing step 700, an etching procedure may be performed to separate the NAND channel 310 and the conductive material of each pier 305 into the NAND channel 310-a and the bit line 155-a (e.g., a first portion of the first conductive material) at the first side of the piers 305 (e.g., in the positive y direction) and into the NAND channel 310-b and the bit line 155-b (e.g., a second portion of the first conductive material) at the second side of the piers 305 (in the negative y direction). For example, to separate the NAND channels 310 and the bit lines 155, a lateral etch may be performed on each pier 305 of the plurality of piers 305 after exhuming the sacrificial material 505 between adjacent piers 305, where the exhumation of such sacrificial material 505 may increase the accuracy (e.g., control) of the lateral etch of the NAND channels 310.

In such examples, with respect to the view 801 (e.g., top view), during the etching procedure, a first etch may be performed (e.g., a wet etch, plasma etch, laser etch, an evaporation etch, or the like) to remove a portion of the NAND channel 310 from a third side (e.g., in the negative x direction) of each pier 305 and remove a portion of the NAND channel 310 from a fourth side (e.g., in the positive x direction) of each pier 305 to form the NAND channel 310-a and the NAND channel 310-b. Additionally, a second etch may be performed (e.g., a wet etch, plasma etch, laser etch, an evaporation etch, or the like) to remove a portion of the first conductive material from the third and fourth side of each pier to form the bit line 155-a and the bit line 155-b. The first and second etch may result in the core dielectric material 315 on the third side and fourth side of each pier to be exposed.

In such examples, the removed portions of the NAND channel 310 may be less than the removed portions of the first conductive material, such that an edge of the NAND channel 310-a may be offset from an edge of the bit line 155-a and an edge of the NAND channel 310-b may be offset from an edge of the bit line 155-a, as described herein with reference to FIG. 3. Such first and second etches may be selective etches, such that the correct amount of material may be removed, leading to the offset between the edges of NAND channels 310 and the edges of the bit lines 155.

In response to performing the etching procedure, a dielectric material 320 may be deposited into the remaining portions of the trenches 420 (e.g., channel sealing and filling), such that the dielectric material 320 is coupled with the core dielectric material 315 of each pier 305 and provides insulation between the NAND channels 310 and the bit lines 155. In some examples, with respect to the views 802 and 803, the dielectric material 320 may extend through to the substrate 415 to separate (e.g., decouple) the NAND channel 310-a from the NAND channel 310-b of each pier 305. Alternatively, as illustrated in the view 803, the dielectric material 320 may separate the walls of the NAND channel 310-a and the NAND channel 310-b, while the NAND channel 310-a and the NAND channel 310-b may be coupled at a bottom portion of each pier 305.

FIG. 9 shows an example of a processing step 900 that supports memory architectures with split pillars in accordance with examples as disclosed herein. Aspects of the processing step 900 may be implemented to manufacture the memory device 300 as described herein with reference to FIG. 3. The processing step 900 may be performed in response to (e.g., after) the processing step 800 and be performed to form the word lines 165 at each level of the memory device 300.

In some examples, a metallization procedure (e.g., replacement gate (RG)) may be performed to replace the nitride materials 405 of the stack of materials 403 with the second conductive material, thereby forming multiple word lines 165. As described herein, each word line 165 may be coupled with a respective portion of the NAND channel 310-a and a respective portion of the NAND channel 310-b. That is, each word line 165 may be coupled with a respective memory cell of the NAND channel 310-a and a respective memory cell of the NAND channel 310-b.

For example, with respect to the views 901, 902, and 903, the word line 165-a may be coupled with a first memory cell of the NAND channel 310-a and a first memory cell of the NAND channel 310-b of each pier 305 of the multiple piers 305, where the first memory cells of the NAND channels 310 of each pier may be at a first level of the piers 305. Similarly, a word line 165-b may be coupled with a second memory cell of the NAND channel 310-a and a second memory cell of the NAND channel 310-b of each pier 305 of the multiple piers 305, where the second memory cells of the NAND channels 310 of each pier 305 may be at a second level of piers 305. Accordingly, as described herein with reference to FIG. 3, each word line 165 may be at a respective level of the memory device 300, such that each word line 165 may be used to access memory cells 105 of the piers 305 at their respective level.

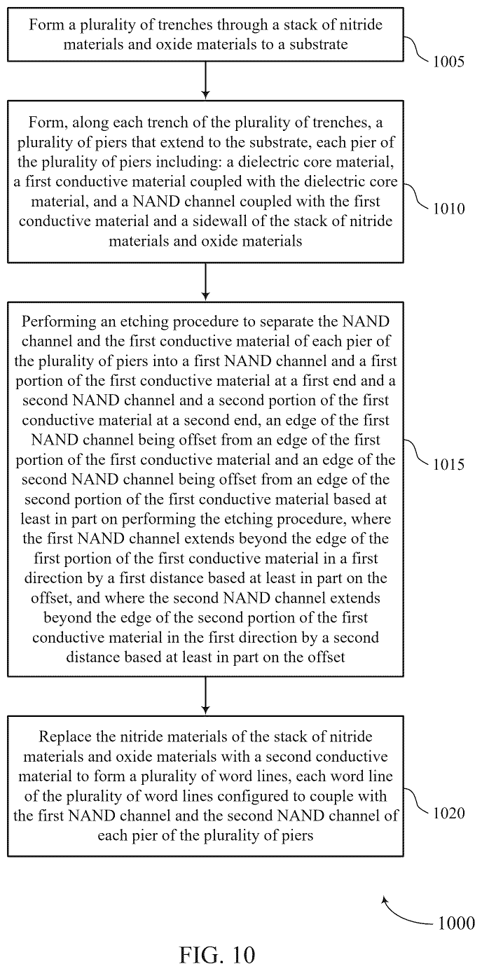

FIG. 10 shows a flowchart illustrating a method 1000 that supports memory architectures with split pillars in accordance with examples as disclosed herein. The operations of method 1000 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 1005, the method may include forming a plurality of trenches through a stack of nitride materials and oxide materials to a substrate.

At 1010, the method may include forming, along each trench of the plurality of trenches, a plurality of piers that extend to the substrate, each pier of the plurality of piers including: a core dielectric material, a first conductive material coupled with the core dielectric material, and a NAND channel coupled with the first conductive material and a sidewall of the stack of nitride materials and oxide materials.

At 1015, the method may include performing an etching procedure to separate the NAND channel and the first conductive material of each pier of the plurality of piers into a first NAND channel and a first portion of the first conductive material at a first end and a second NAND channel and a second portion of the first conductive material at a second end, where an edge of the first NAND channel is offset from an edge of the first portion of the first conductive material and an edge of the second NAND channel is offset from an edge of the second portion of the first conductive material based at least in part on performing the etching procedure.

At 1020, the method may include replacing the nitride materials of the stack of nitride materials and oxide materials with a second conductive material to form a plurality of word lines, each word line of the plurality of word lines configured to couple with the first NAND channel and the second NAND channel of each pier of the plurality of piers.

In some examples, an apparatus (e.g., a manufacturing system) as described herein may perform a method or methods, such as the method 1000. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for forming a plurality of trenches through a stack of nitride materials and oxide materials to a substrate; forming, along each trench of the plurality of trenches, a plurality of piers that extend to the substrate, each pier of the plurality of piers including: a core dielectric material, a first conductive material coupled with the core dielectric material, and a NAND channel coupled with the first conductive material and a sidewall of the stack of nitride materials and oxide materials; performing an etching procedure to separate the NAND channel and the first conductive material of each pier of the plurality of piers into a first NAND channel and a first portion of the first conductive material at a first end and a second NAND channel and a second portion of the first conductive material at a second end, an edge of the first NAND channel being offset from an edge of the first portion of the first conductive material and an edge of the second NAND channel being offset from an edge of the second portion of the first conductive material based at least in part on performing the etching procedure, where the edge of the first NAND channel extends beyond the edge of the first portion of the first conductive material in a first direction by a first distance based at least in part on the offset, and where the edge of the second NAND channel extends beyond the edge of the second portion of the first conductive material in the first direction by a second distance based at least in part on the offset; and replacing the nitride materials of the stack of nitride materials and oxide materials with a second conductive material to form a plurality of word lines, each word line of the plurality of word lines configured to couple with the first NAND channel and the second NAND channel of each pier of the plurality of piers.

Aspect 2: The method, apparatus, or non-transitory computer-readable medium of aspect 1, further including operations, features, circuitry, logic, means, or instructions, or any combination thereof for depositing, in each trench of the plurality of trenches, a sacrificial material, where forming the plurality of piers is based at least in part on depositing the sacrificial material in each trench.

Aspect 3: The method, apparatus, or non-transitory computer-readable medium of aspect 2, further including operations, features, circuitry, logic, means, or instructions, or any combination thereof for performing a second etching procedure to exhume the sacrificial material from each trench of the plurality of trenches based at least in part on forming the plurality of piers.

Aspect 4: The method, apparatus, or non-transitory computer-readable medium of any of aspects 2 through 3, where forming the plurality of piers includes operations, features, circuitry, logic, means, or instructions, or any combination thereof for etching a plurality of cavities into the sacrificial material along each trench of the plurality of trenches; forming the NAND channel in each cavity of the plurality of cavities; etching a second plurality of cavities into the NAND channel; forming the first conductive material into the second plurality of cavities; etching a third plurality of cavities into the first conductive material; and depositing the core dielectric material into the third plurality of cavities to form the plurality of piers.

Aspect 5: The method, apparatus, or non-transitory computer-readable medium of any of aspects 2 through 3, where the plurality of piers are formed according to a sequential deposition of the NAND channel, the first conductive material, and the core dielectric material.

Aspect 6: The method, apparatus, or non-transitory computer-readable medium of any of aspects 1 through 4, further including operations, features, circuitry, logic, means, or instructions, or any combination thereof for depositing, based at least in part on performing the etching procedure, a dielectric material into each trench of the plurality of trenches to form a dielectric channel, where the dielectric channel is configured to couple the core dielectric material of each pier of the plurality of piers.

Aspect 7: The method, apparatus, or non-transitory computer-readable medium of any of aspects 1 through 6, where performing the etching procedure includes operations, features, circuitry, logic, means, or instructions, or any combination thereof for removing a portion of the NAND channel and a portion of the first conductive material from a first side of each pier of the plurality of piers and from a second side of each pier of the plurality of piers, where the removed portion of the NAND channel is less than the removed portion of the first conductive material.

Aspect 8: The method, apparatus, or non-transitory computer-readable medium of any of aspects 1 through 7, further including operations, features, circuitry, logic, means, or instructions, or any combination thereof for forming the stack of nitride and oxide materials over the substrate, where forming the plurality of trenches is based at least in part on forming the stack of nitride and oxide materials.

Aspect 9: The method, apparatus, or non-transitory computer-readable medium of any of aspects 1 through 8, where the first NAND channel and the first portion of the first conductive material of each pier of the plurality of piers have one of a hemicylindrical form, a semielliptical form, a rounded rectangular form, or a combination thereof, and the second NAND channel and the second portion of the first conductive material of each pier of the plurality of piers have one of the hemicylindrical form, the semielliptical form, the rounded rectangular form, or a combination thereof.

Aspect 10: The method, apparatus, or non-transitory computer-readable medium of any of aspects 1 through 9, where the etching procedure includes one of a wet etching procedure, an evaporation etching procedure, a plasma etching procedure, or a laser etching procedure.

Aspect 11: The method, apparatus, or non-transitory computer-readable medium of any of aspects 1 through 10, where the first NAND channel of each pier of the plurality of piers correspond to a plurality of first memory cells, and the second NAND channel of each pier of the plurality of piers correspond to a plurality of second memory cells.

Aspect 12: The method, apparatus, or non-transitory computer-readable medium

of any of aspects 1 through 11, where the first portion of the first conductive material of each pier of the plurality of piers forms a first bit line and the second portion of the first conductive material of each pier of the plurality of piers forms a second bit line.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 13: A memory device, including: a plurality of piers each including a first NAND channel coupled with a first bit line at a first end and a second NAND channel coupled with a second bit line at a second end, an edge of the first NAND channel being offset from an edge of the first bit line and an edge of the second NAND channel being offset from an edge of the second bit line, where the edge of the first NAND channel extends beyond the edge of the first bit line in a first direction by a first distance based at least in part on the offset, and where the edge of the second NAND channel extends beyond the edge of the second bit line in the first direction by a second distance based at least in part on the offset; a dielectric material separating the first NAND channel and the first bit line from the second NAND channel and the second bit line of each pier of the plurality of piers; and a plurality of word lines each coupled with the first NAND channel and the second NAND channel of each pier of the plurality of piers.

Aspect 14: The memory device of aspect 13, where the first NAND channel and the first bit line of each pier of the plurality of piers have one of a hemicylindrical form, a semielliptical form, a rounded rectangular form, or a combination thereof, and the second NAND channel and the second bit line of each pier of the plurality of piers have one of the hemicylindrical form, the semielliptical form, the rounded rectangular form, or a combination thereof.

Aspect 15: The memory device of any of aspects 13 through 14, where each pier of the plurality of piers includes a core dielectric material, the core dielectric material of each pier of the plurality of piers being coupled with the dielectric material.

Aspect 16: The memory device of any of aspects 13 through 15, where the first NAND channel of each pier of the plurality of piers forms a plurality of first memory cells, and the second NAND channel of each pier of the plurality of piers forms a plurality of second memory cells.

Aspect 17: The memory device of any of aspects 13 through 16, where a third distance between the edge of the first NAND channel and the edge of the second NAND channel is less than a fourth distance between the edge of the first bit line and the edge of the second bit line.

Aspect 18: The memory device of any of aspects 13 through 16, where the first distance and the second distance are equivalent.

Aspect 19: The memory device of any of aspects 13 through 17, further including: a plurality of second piers, each second pier of the plurality of second piers including a third NAND channel coupled with a third bit line at a third end and a fourth NAND channel coupled with a fourth bit line at a fourth end, where an edge of the third NAND channel is offset from an edge of the third bit line and an edge of the fourth NAND channel is offset from an edge of the fourth bit line; and a second dielectric material separating the third NAND channel and the third bit line from the fourth NAND channel and the fourth bit line of each second pier of the plurality of second piers, where each word line of the plurality of word lines is coupled with the third NAND channel and the fourth NAND channel of each second pier of the plurality of second piers.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a plurality of piers each comprising a first not AND (NAND) channel coupled with a first bit line at a first end and a second NAND channel coupled with a second bit line at a second end, an edge of the first NAND channel being offset from an edge of the first bit line and an edge of the second NAND channel being offset from an edge of the second bit line, wherein the edge of the first NAND channel extends beyond the edge of the first bit line in a first direction by a first distance based at least in part on the offset, and wherein the edge of the second NAND channel extends beyond the edge of the second bit line in the first direction by a second distance based at least in part on the offset;
a dielectric material separating the first NAND channel and the first bit line from the second NAND channel and the second bit line of each pier of the plurality of piers; and
a plurality of word lines each coupled with the first NAND channel and the second NAND channel of each pier of the plurality of piers.

2. The memory device of claim 1, wherein the first NAND channel and the first bit line of each pier of the plurality of piers have one of a hemicylindrical form, a semielliptical form, a rounded rectangular form, or a combination thereof, and the second NAND channel and the second bit line of each pier of the plurality of piers have one of the hemicylindrical form, the semielliptical form, the rounded rectangular form, or a combination thereof.

3. The memory device of claim 1, wherein each pier of the plurality of piers comprises a core dielectric material, the core dielectric material of each pier of the plurality of piers being coupled with the dielectric material.

4. The memory device of claim 1, wherein the first NAND channel of each pier of the plurality of piers forms a plurality of first memory cells, and the second NAND channel of each pier of the plurality of piers forms a plurality of second memory cells.

5. The memory device of claim 1, wherein a third distance between the edge of the first NAND channel and the edge of the second NAND channel is less than a fourth distance between the edge of the first bit line and the edge of the second bit line.

6. The memory device of claim 1, wherein the first distance and the second distance are equal.

7. The memory device of claim 1, further comprising:
a plurality of second piers, each second pier of the plurality of second piers comprising a third NAND channel coupled with a third bit line at a third end and a fourth NAND channel coupled with a fourth bit line at a fourth end, wherein an edge of the third NAND channel is offset from an edge of the third bit line and an edge of the fourth NAND channel is offset from an edge of the fourth bit line; and
a second dielectric material separating the third NAND channel and the third bit line from the fourth NAND channel and the fourth bit line of each second pier of the plurality of second piers, wherein each word line of the plurality of word lines is coupled with the third NAND channel and the fourth NAND channel of each second pier of the plurality of second piers.

8. A method for manufacturing a memory device, comprising:
forming a plurality of trenches through a stack of nitride materials and oxide materials to a substrate;
forming, along each trench of the plurality of trenches, a plurality of piers that extend to the substrate, each pier of the plurality of piers comprising: a core dielectric material, a first conductive material coupled with the core dielectric material, and a NAND channel coupled with the first conductive material and a sidewall of the stack of nitride materials and oxide materials;
performing an etching procedure to separate the NAND channel and the first conductive material of each pier of the plurality of piers into a first NAND channel and a first portion of the first conductive material at a first end and a second NAND channel and a second portion of the first conductive material at a second end, an edge of the first NAND channel being offset from an edge of the first portion of the first conductive material and an edge of the second NAND channel being offset from an edge of the second portion of the first conductive material based at least in part on performing the etching procedure, wherein the edge of the first NAND channel extends beyond the edge of the first portion of the first conductive material in a first direction by a first distance based at least in part on the offset, and wherein the edge of the second NAND channel extends beyond the edge of the second portion of the first conductive material in the first direction by a second distance based at least in part on the offset; and
replacing the nitride materials of the stack of nitride materials and oxide materials with a second conductive material to form a plurality of word lines, each word line of the plurality of word lines configured to couple with the first NAND channel and the second NAND channel of each pier of the plurality of piers.

9. The method of claim 8, further comprising:
depositing, in each trench of the plurality of trenches, a sacrificial material, wherein forming the plurality of piers is based at least in part on depositing the sacrificial material in each trench.

10. The method of claim 9, further comprising:
performing a second etching procedure to exhume the sacrificial material from each trench of the plurality of trenches based at least in part on forming the plurality of piers.

11. The method of claim 9, wherein forming the plurality of piers comprises:
etching a plurality of cavities into the sacrificial material along each trench of the plurality of trenches;
forming the NAND channel in each cavity of the plurality of cavities;
etching a second plurality of cavities into the NAND channel;
forming the first conductive material into the second plurality of cavities;
etching a third plurality of cavities into the first conductive material; and
depositing the core dielectric material into the third plurality of cavities to form the plurality of piers.

12. The method of claim 9, wherein the plurality of piers are formed according to a sequential deposition of the NAND channel, the first conductive material, and the core dielectric material.

13. The method of claim 8, further comprising:
depositing, based at least in part on performing the etching procedure, a dielectric material into each trench of the plurality of trenches to form a dielectric channel, wherein the dielectric channel is configured to couple the core dielectric material of each pier of the plurality of piers.

14. The method of claim 8, wherein performing the etching procedure comprises:
removing a portion of the NAND channel and a portion of the first conductive material from a first side of each pier of the plurality of piers and from a second side of each pier of the plurality of piers, wherein the removed portion of the NAND channel is less than the removed portion of the first conductive material.

15. The method of claim 8, further comprising:
forming the stack of nitride and oxide materials over the substrate, wherein forming the plurality of trenches is based at least in part on forming the stack of nitride and oxide materials.

16. The method of claim 8, wherein the first NAND channel and the first portion of the first conductive material of each pier of the plurality of piers have one of a hemicylindrical form, a semielliptical form, a rounded rectangular form, or a combination thereof, and the second NAND channel and the second portion of the first conductive material of each pier of the plurality of piers have one of the hemicylindrical form, the semielliptical form, the rounded rectangular form, or a combination thereof.

17. The method of claim 8, wherein the etching procedure comprises one of a wet etching procedure, an evaporation etching procedure, a plasma etching procedure, or a laser etching procedure.

18. The method of claim 8, wherein the first NAND channel of each pier of the plurality of piers correspond to a plurality of first memory cells, and the second NAND channel of each pier of the plurality of piers correspond to a plurality of second memory cells.

19. The method of claim 8, wherein:
the first portion of the first conductive material of each pier of the plurality of piers forms a first bit line, and
the second portion of the first conductive material of each pier of the plurality of piers forms a second bit line.

20. A memory device formed by a process comprising:
forming a plurality of trenches through a stack of nitride materials and oxide materials to a substrate;
forming, along each trench of the plurality of trenches, a plurality of piers that extend to the substrate, each pier of the plurality of piers comprising: a core dielectric material, a first conductive material coupled with the core dielectric material, and a NAND channel coupled with the first conductive material and a sidewall of the stack of nitride materials and oxide materials;
performing an etching procedure to separate the NAND channel and the first conductive material of each pier of the plurality of piers into a first NAND channel and a first portion of the first conductive material at a first end and a second NAND channel and a second portion of the first conductive material at a second end, an edge of the first NAND channel being offset from an edge of the first portion of the first conductive material and an edge of the second NAND channel being offset from an edge of the second portion of the first conductive material based at least in part on performing the etching procedure, wherein the edge of the first NAND channel extends beyond the edge of the first portion of the first conductive material in a first direction by a first distance based at least in part on the offset, and wherein the edge of the second NAND channel extends beyond the edge of the second portion of the first conductive material in the first direction by a second distance based at least in part on the offset; and
replacing the nitride materials of the stack of nitride materials and oxide materials with a second conductive material to form a plurality of word lines, each word line of the plurality of word lines configured to couple with the first NAND channel and the second NAND channel of each pier of the plurality of piers.
